(19) United States
(12) Patent Application Publication
(10) Pub. No.: US 2007/0158794 A1
(43) Pub. Date: Jul. 12, 2007

(54) Package structure of thin lead-frame

(75) Inventor: Chi-Jang Lo, Hukou Shiang (TW)

Correspondence Address: BIRCH STEWART KOLASCH & BIRCH, PO BOX 747, FALLS CHURCH, VA, 22040-0747, US

(73) Assignee: Powertech Technology Inc.

(21) Appl. No.: 11/325,437

(22) Filed: Jan. 5, 2006

(51) Int. Cl. H01L 23/495

(52) U.S. Cl. 257/666

(57) ABSTRACT

An assembly structure of thin lead-frame is provided. A lead-frame includes the plurality of leads and a layer located on the extension of the inner lead to bear a die. Then the molding compound is covered the die, the layer, and the plurality of leads but exposed the outer lead to electrically connect with different electric circuit substrates. The inner leads used as a die pad directly may reduce the size of the package. Furthermore, the assembly cost may drop dramatically and facilitate the assembly process due to the invention is totally different than prior package assembly method.

### BACKGROUND OF THE INVENTION

1. FIELD OF THE INVENTION

The present invention relates to a die assembly structure and more especially, relates to a tiny volume, thin and flat lead-frame structure.

2. DESCRIPTION OF THE PRIOR ART

The aggregate density increment of the integrate circuit (IC) caused the requirement of reduce the package size became the tendency within the semi-conductor assembly technology field. How to reduce the die size in the package is the tendency that enterprises are going to focus on.

In order to reduce the size of the die and the lead-frame combination, the traditional prior assembly method are: stack method and lead-frame method. Stack method covers several dies, have different functions, into one single package. It also has two different types of stack method: one is to stack un-assemble individual dies, and another way is to stack the package that assembled complete. However, the package thickness of second stack method may be at least twice as thick as the individual die. As this result, the second stack method is weeded out the semi-conductor assembly technology stage by stage.

About the traditional lead-frame method, please refer FIG.1. A lead-frame assembly method includes a die 10 and a lead-frame 12. There is a die pad 14 attached on the center of the lead-frame 12, and provides the ability for the die 10 to stick on steadily to forming the combination of the die 10 and the lead-frame 12. However, the prior lead-frame structure has to attach the die pad 14 to carry the die 10, the package size may larger and the cost may higher.

### SUMMARY OF THE INVENTION

According to the issue mentioned previously, the present invention provides a structure of thin lead-frame to improve the mentioned issue efficiently.

One of objects of this invention to provide a structure of thin lead-frame using the inner leads as the die pad directly may reduce the package size dramatically.

Another object of this invention is to provide the structure of thin lead-frame without the traditional die pad to drop the assembly cost and facilitate the assembly process.

Another object of this invention is to provide the structure of thin lead-frame. The package application field will become diversify due to the structure reduce the size of package.

Accordingly, one embodiment of the present invention provides a structure of thin lead-frame package. It includes a lead-frame, which contains the plurality of first leads and the plurality of second leads, and each first lead and each second lead has an inner lead and an outer lead individually. A layer located on the extension of every inner lead of the first lead. There is the plurality of electric terminals positioned on the die, which are electrically connected with a first lead and a second lead. Then cover these components by a molding compound but expose the outer lead.

These and other objects will appear more fully from the specification below.

### BRIEF DESCRIPTION OF THE DRAWINGS

FIG. 1 is a cross-sectional diagram illustrating the prior art of lead-frame structure; and

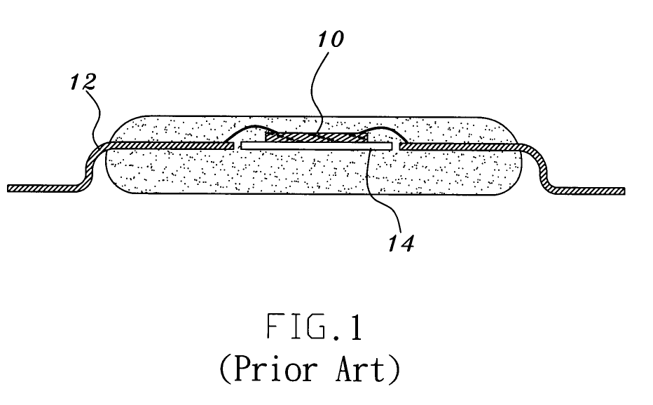

FIG. 2 is a cross-sectional diagram illustrating the structure in accordance with an embodiment of the present invention.

### DETAILED DESCRIPTION OF THE INVENTION

The invention provides a structure of thin lead-frame, which may apply in the thin small outline packaging to reduce the size of package, to make the structure thinner and flatter.

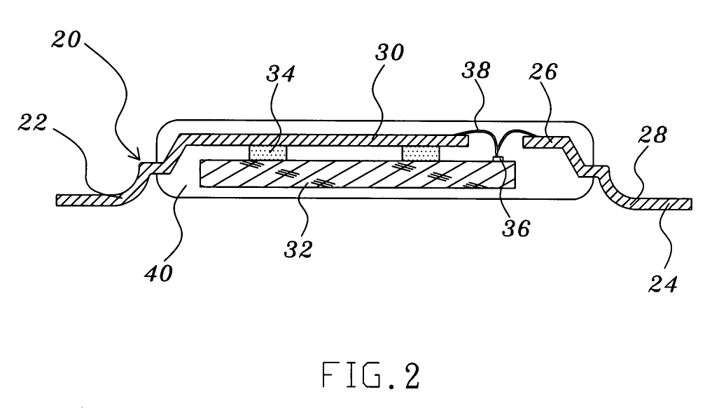

Please refer FIG. 2, the thin lead-frame structure includes a lead-frame 20 (metal material), which contains the plurality of first leads 22 and the plurality of second leads 24, and each first lead 22 and each second lead 24 has an inner lead 26 and an outer lead 28 individually. A layer 30 located on the extension of the inner lead 26 of the first lead 22. The die 32 is located under the layer 30 by attached a junction component 34 (insulating material, such as insulating tape or insulating compound), which can hang the die 32 on the layer 30. The die 32 has the plurality of electric terminals 36 connected the wires 38 (aurum material, Au), the first leads 22 and the second leads 24 by wire bonding. Then a molding compound 40 made of epoxy, covers the inner leads 26, the die 32 and the junction component 34 and just expose the outer leads 28. Therefore, the expose outer leads 28 may electrically connected to different substrates.

The present invention is totally different than the traditional prior lead-frame structure due to omit the prior die pad and identify the inner lead as the die pad directly. As this result, the package size and the material cost may reduce dramatically and facilitate the assembly process. Eventually, because of the reduction of the package size and improve as more thinner and more flatter, the application field of the structure may become diversify.

Although the present invention has been explained in relation to its preferred embodiment, it is to be understood that other modifications and variation can be made without departing the spirit and scope of the invention as hereafter claimed.

What is claimed is:

1. A structure of thin lead-frame comprising:
a lead-frame with a plurality of first leads and a plurality of second leads, wherein each of said plurality of first leads and each of said plurality of second leads have an inner lead and an outer lead individually, and said inner leads of said first leads extended as a layer;
a die with a plurality of electric terminals electrically connected with said plurality of first leads and said plurality of second leads; and
a molding compound used to cover said lead-frame, said plurality of inner leads, said die, said plurality of electric terminals, and said layer, but expose said outer leads.

2. The structure of thin lead-frame according to claim 1, wherein said die is attached on said layer by a junction component.

3. The assembly structure of thin lead-frame according to claim 2, wherein said junction component is made of insulating material.

4. The structure of thin lead-frame according to claim 2, wherein said junction component is insulating tape or insulating compound.

5. The structure of thin lead-frame according to claim 1, wherein said die electrically connected with said plurality of first leads and said plurality of second leads by a plurality of wires.

6. The structure of thin lead-frame according to claim 5, wherein said plurality wires are made of aurum material (Au).

7. The structure of thin lead-frame according to claim 1, wherein said molding compound is made of epoxy.

8. The structure of thin lead-frame according to claim 1, wherein said die is located on said layer in a way of suspension.

9. The structure of thin lead-frame according to claim 1, wherein said lead-frame is made of metal material.
